(19) United States
(12) Patent Application Publication
(10) Pub. No.: US 2026/0173911 A1
(43) Pub. Date: Jun. 18, 2026

(54) ELECTRONIC DEVICE AND METHOD FOR MANUFACTURING THE SAME

(71) Applicants: Innolux Corporation, Miaoli County (TW); nD-HI Technologies Lab, Inc., Taipei City (TW)

(72) Inventors: Shu-Hsien Wu, Miaoli County (TW); Tsung-Yuan Wu, Miaoli County (TW); Chih-Chao Chuang, Miaoli County (TW); Ho-Ming Tong, Taipei City (TW); Szu-Yen Yu, Miaoli County (TW)

(73) Assignees: Innolux Corporation, Miaoli County (TW); nD-HI Technologies Lab, Inc., Taipei City (TW)

(21) Appl. No.: 19/393,500

(22) Filed: Nov. 18, 2025

Related U.S. Application Data
(60) Provisional application No. 63/734,195, filed on Dec. 16, 2024.

(30) Foreign Application Priority Data
Jul. 16, 2025 (CN) 202510982825.6

(51) Int. Cl. H01L 23/538; H01L 21/48; H01L 23/00; H01L 23/367; H01L 23/373; H01L 25/065

(52) U.S. Cl. CPC H10W 70/611; H10W 40/255; H10W 42/121; H10W 70/05; H10W 70/65; H10W 70/685; H10W 40/22; H10W 90/00; H10W 90/734

(57) ABSTRACT

Provided are an electronic device and a method for manufacturing the same. The electronic device includes at least one electronic unit and a connection substrate. The connection substrate is electrically connected to the electronic unit and includes a first base structure and a second base structure disposed between the first base structure and the electronic unit. The first base structure includes a first insulation layer and a first heat dissipation structure disposed in the first insulation layer, and the second base structure includes a second insulation layer and a second heat dissipation structure disposed in the second insulation layer. A thickness of the first insulation layer is greater than a thickness of the second insulation layer, and the first heat dissipation structure overlaps with the second heat dissipation structure.

### CROSS-REFERENCE TO RELATED APPLICATION

This application claims the priority benefits of U.S. provisional application Ser. No. 63/734,195, filed on Dec. 16, 2024, and China application serial no. 202510982825.6, filed on Jul. 16, 2025. The entirety of each of the above-mentioned patent applications is hereby incorporated by reference herein and made a part of this specification.

### BACKGROUND

### Technical Field

The disclosure relates to an electronic device and a method for manufacturing the same, and particularly relates to an electronic device having improved reliability and a method for manufacturing the same.

### Description of Related Art

In current semiconductor packaging technology, mounting electronic units with different functions on the same substrate is one of the manners to enhance the performance of electronic devices. As electronic devices continue to be developed toward lighter, thinner, shorter, and smaller dimensions and performance requirements for electronic devices from users continue to increase, the density of electronic units mounted on the substrates is also increasing. A coreless substrate is a type of substrate commonly used in advanced packaging to meet the demand for more input/output pads (I/O pads) or lighter and thinner requirements. However, coreless substrates still face challenges in terms of support, warpage, and/or heat dissipation efficiency. Therefore, persons skilled in the art continue to improve coreless substrates to meet current or future requirements.

### SUMMARY

The disclosure provides an electronic device having improved reliability and method for manufacturing the same.

According to an embodiment of the disclosure, an electronic device includes at least one electronic unit, a connection substrate, and a stiffener. The connection substrate is electrically connected to the electronic unit and includes a first base structure and a second base structure disposed between the first base structure and the electronic unit. The stiffener surrounds the connection substrate. The first base structure includes a first insulation layer and a first heat dissipation structure disposed in the first insulation layer, and the second base structure includes a second insulation layer and a second heat dissipation structure disposed in the second insulation layer. The first heat dissipation structure overlaps with the second heat dissipation structure, and the first heat dissipation structure and the second heat dissipation structure are in contact with at least a portion of the stiffener.

According to an embodiment of the disclosure, a method for manufacturing an electronic device includes the following. An electronic unit is provided. A connection substrate is provided. Also, a stiffener surrounding the connection substrate is provided. The connection substrate is electrically connected to the electronic unit and includes a first base structure and a second base structure disposed between the first base structure and the electronic unit. The first base structure includes a first insulation layer and a first heat dissipation structure formed in the first insulation layer, and the second base structure includes a second insulation layer and a second heat dissipation structure formed in the second insulation layer. The first heat dissipation structure overlaps with the second heat dissipation structure, and the first heat dissipation structure and the second heat dissipation structure are in contact with at least a portion of the stiffener.

Based on the above, in the embodiments of the disclosure, the first heat dissipation structure of the connection substrate is designed to overlap with the second heat dissipation structure, and the first heat dissipation structure and the second heat dissipation structure are in contact with at least a portion of the stiffener, which may help improve the heat dissipation efficiency and support of the connection substrate, thereby improving the reliability of the electronic device.

To make the foregoing features and advantages of the disclosure more comprehensible, embodiments are specifically provided below and described in detail with reference to the accompanying drawings as follows.

### BRIEF DESCRIPTION OF THE DRAWINGS

The drawings are included to provide a further understanding of the disclosure, and the drawings are incorporated in and constitute a part of this specification. The drawings illustrate embodiments of the disclosure and, together with the description, serve to explain the principles of the disclosure.

FIG. 1 is a cross-sectional schematic diagram of an electronic device according to an embodiment of the disclosure.

FIG. 2 is a cross-sectional schematic diagram of a connection substrate in FIG. 1 according to an embodiment of the disclosure.

FIG. 3 is an exploded schematic diagram of a wiring structure, a heat dissipation structure, and an electronic unit according to an embodiment of the disclosure.

FIG. 4 is an exploded schematic diagram of a wiring structure, a support layer, and an electronic unit according to an embodiment of the disclosure.

FIG. 5A and FIG. 5B are cross-sectional schematic diagrams of a method for manufacturing a connection substrate according to an embodiment of the disclosure.

FIG. 6A and FIG. 6B and FIG. 7A and FIG. 7B are cross-sectional schematic diagrams of partial steps of a method for forming a redistribution layer in FIG. 5B according to different embodiments of the disclosure.

FIG. 8 is a cross-sectional schematic diagram of a connection substrate according to another embodiment of the disclosure.

### DESCRIPTION OF THE EMBODIMENTS

The disclosure may be understood by referring to the following detailed description together with the accompanying drawings. It should be noted that, in order to enable readers to easily understand and for the simplicity of the drawings, multiple drawings in the disclosure merely show a part of the package structure, and specific components in the drawings are not drawn according to actual scale. In addition, the number and dimensions of each component in the drawings are merely for illustration and are not used to limit the scope of the disclosure. For example, for clarity, the relative dimensions, thickness, and positions of each film layer, region, and/or structure may be reduced or enlarged.

Certain terms are used throughout the specification and the appended claims of the disclosure to refer to specific components. Persons skilled in the art should understand that electronic device manufacturers may refer to the same component by different names. This document does not intend to distinguish between components that have the same function but different names. In the following specification and claims, terms such as “have” and “include” are open-ended terms, and therefore should be interpreted to mean “include but not limited to . . . ”.

In this document, “one component is set on another component” is for the convenience of describing the relative position between the component and the another component, and is not used to limit the process steps or sequence of the component and the another component.

The directional terms mentioned in this document, such as: “upper”, “lower”, “front”, “rear”, “left”, “right”, are merely references to the directions of the accompanying drawings. Therefore, the directional terms used are for illustration and are not used to limit the disclosure. It should be understood that when a component or film layer is referred to as being set “on” another component or film layer or “connected” to another component or film layer, the component or film layer may be directly on the another component or film layer or directly connected to the another component or film layer, or there are inserted components or film layers between the two (non-direct situation). Conversely, when a component or film layer is referred to as being “directly” “on” another component or film layer or “directly connected” to another component or film layer, there are no inserted components or film layers between the two. In addition, when a component or film layer is referred to as overlapping with another component, the component or film layer at least partially overlaps with the another component or film layer.

The terms “about”, “approximately”, “substantially”, or “roughly” mentioned in this document generally represent falling within a 10% range of a given value or range, or represent falling within a 5%, or 0.5% range of a given value or range. In addition, the phrases “a given range is from a first value to a second value”, “a given range falls within the range from a first value to a second value” indicate that the given range includes the first value, the second value, and other values therebetween.

In some embodiments of the disclosure, terms regarding bonding and connection such as “connect”, “interconnect”, unless specifically defined, may refer to two structures being in direct contact, or may also refer to two structures not being in direct contact, wherein other structures are set between the two structures. Terms regarding bonding and connection may also include situations where both structures are movable, or both structures are fixed. In addition, the terms “electrically connect” and “couple” include any direct and indirect electrical connection manners.

In the following embodiments, the same or similar components will adopt the same or similar reference numerals, and redundant description thereof will be omitted. In addition, features in different embodiments may be arbitrarily mixed and matched for use as long as they do not violate the spirit of the invention or conflict with each other, and simple equivalent changes and modifications made according to this specification or claims are still within the scope covered by the disclosure. That is, the following embodiments may replace, recombine, and mix technical features in several different embodiments to complete other embodiments without departing from the spirit of the disclosure. In addition, terms such as “first” and “second” mentioned in this specification or claims are merely used to name different components or distinguish different embodiments or ranges, and are not used to limit the upper or lower limit of the number of components, nor are they used to limit the manufacturing sequence or setting sequence of components.

In the disclosure, the measurement methods for roughness, thickness, length and width may optionally adopt optical microscope (OM) and/or scanning electron microscope (SEM) measurement, but are not limited thereto. For example, the measurement methods for thickness, length and width may adopt optical microscope measurement, and thickness or width may be measured from cross-sectional images in electron microscope, but are not limited thereto. In addition, any two values or directions used for comparison may have certain errors. If a first value equals a second value, it implies that there may be an error of about 10% between the first value and the second value.

The process of the electronic device in the disclosure may exemplify apply wafer-level package (WLP) process, for example, may include Chip-on-Wafer-on-Substrate (CoWoS) technology, but the disclosure is not limited thereto, or may apply panel-level package (PLP) process, for example, may include Chip-on-Panel-on-Substrate (CoPoS) technology, but the disclosure is not limited thereto. In some embodiments, the process of the electronic device in the disclosure may exemplify apply chip last process or chip first process. The electronic device described in the disclosure may apply to high-speed computing modules, power modules, semiconductor package devices, optical communication modules, display devices, light-emitting devices, backlight devices, antenna devices, sensing devices or splicing devices, but the disclosure is not limited thereto.

The following exemplifies exemplary embodiments of the disclosure, in which the same component symbols are used in the drawings and description to represent the same or similar parts.

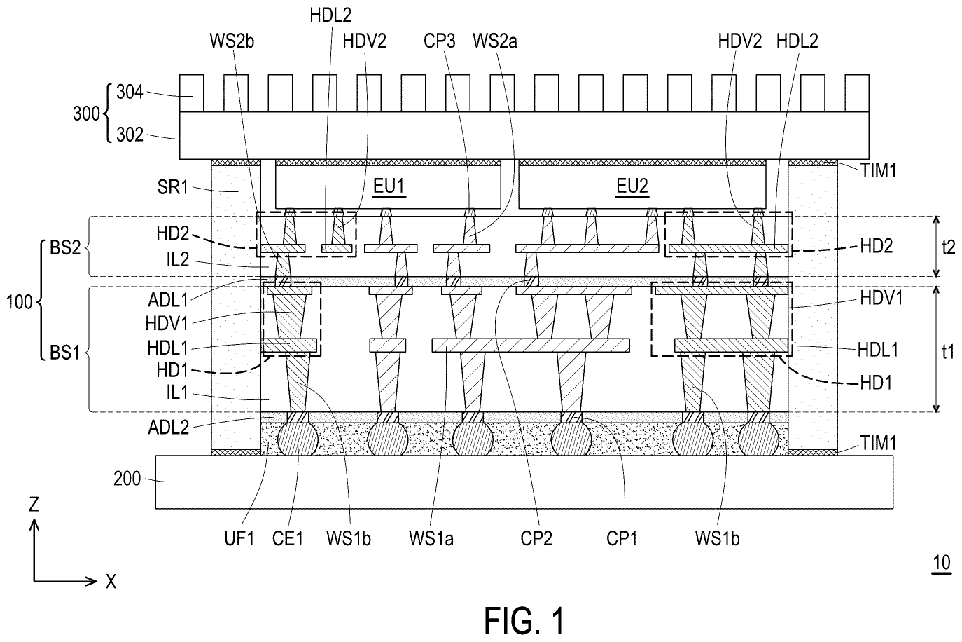

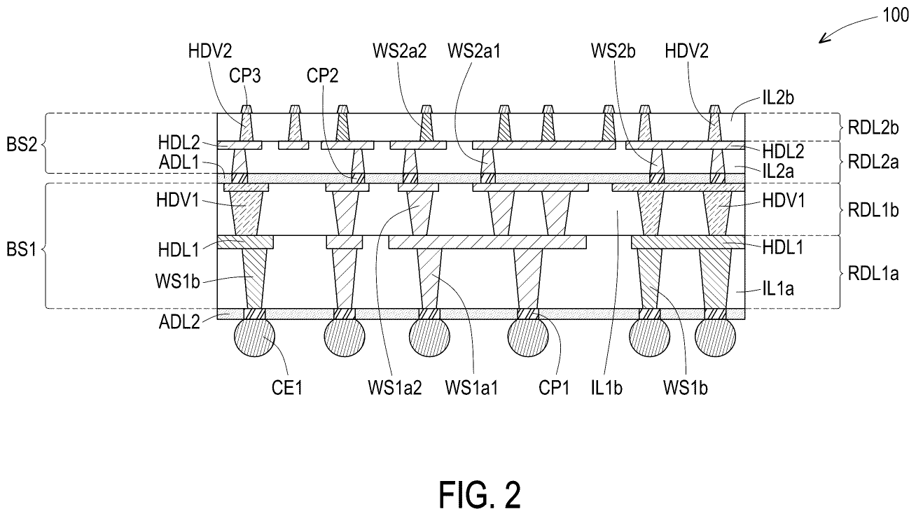

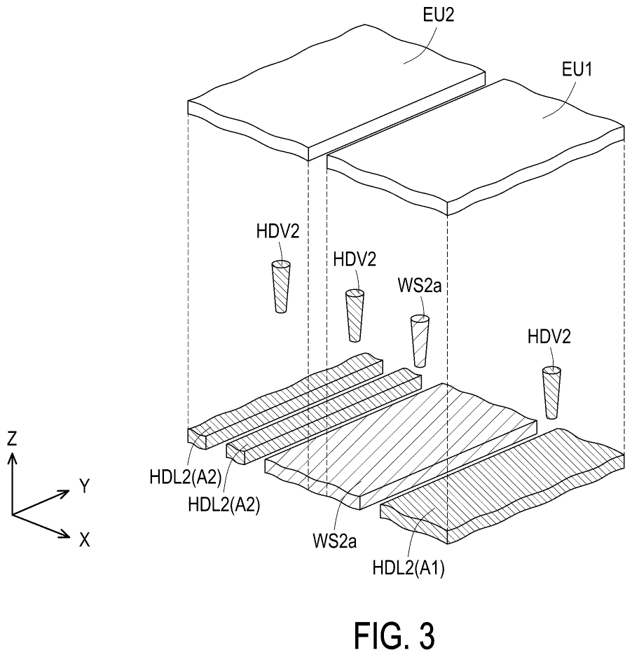

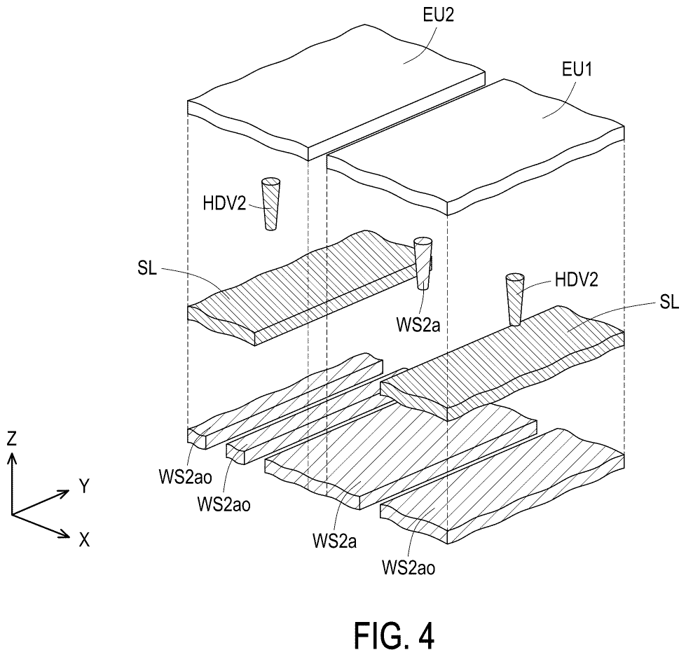

FIG. 1 is a cross-sectional schematic diagram of an electronic device according to an embodiment of the disclosure. FIG. 2 is a cross-sectional schematic diagram of a connection substrate in FIG. 1 according to an embodiment of the disclosure. FIG. 3 is an exploded schematic diagram of a wiring structure, a heat dissipation structure, and an electronic unit according to an embodiment of the disclosure. FIG. 4 is an exploded schematic diagram of a wiring structure, a support layer, and an electronic unit according to an embodiment of the disclosure.

First, referring to FIG. 1, an electronic device 10 includes at least one electronic unit EU1 or EU2 and a connection substrate 100. The connection substrate 100 is electrically connected to the electronic unit EU1 or EU2, and the connection substrate 100 includes a first base structure BS1 and a second base structure BS2 disposed between the first base structure BS1 and the electronic unit EU1 or EU2.

In the present embodiment, the at least one electronic unit EU1 or EU2 may include a plurality of electronic units EU1, EU2 and may be disposed on the connection substrate 100. The electronic units EU1, EU2 may include passive components, active components, or combinations thereof, for example, capacitors, resistors, inductors, variable capacitors, filters, diodes, transistors, sensors, micro-electro-mechanical system (MEMS) components, system-on-chip (SoC), central processing unit (CPU), graphics processing unit (GPU), memory, or logic die components, but are not limited thereto.

In some embodiments, the connection substrate 100 may have panel-level dimensions. For example, the area of the connection substrate 100 may range from 5 cm×5 cm to 100 cm×100 cm, or any suitable dimensions, but the disclosure is not limited thereto. In some embodiments, in the situation where the connection substrate 100 has panel-level dimensions, the connection substrate 100 may apply to fan out panel level package (FOPLP) process. In the present embodiment, the fan out panel level package can significantly improve production capacity compared to wafer-level package because of adopting the connection substrate 100 having panel-level dimensions. Meanwhile, the connection substrate 100 having panel-level dimensions may have a rectangular profile, which can also significantly improve the utilization rate of the connection substrate 100 compared to wafer-level package.

In the present embodiment, the first base structure BS1 includes a first insulation layer IL1 and a first heat dissipation structure HD1 disposed in the first insulation layer IL1. The second base structure BS2 includes a second insulation layer IL2 and a second heat dissipation structure HD2 disposed in the second insulation layer IL2. In the present embodiment, a thickness t1 of the first insulation layer IL1 is greater than a thickness t2 of the second insulation layer IL2, and the first heat dissipation structure HD1 and the second heat dissipation structure HD2 at least partially overlap, which may help improve the heat dissipation efficiency and support of the connection substrate 100 and reduce warpage situations caused by excessive differences in coefficient of thermal expansion (CTE), thereby improving the reliability of the electronic device 10. In some embodiments, in a Z direction, the first base structure BS1 is farther from the electronic unit EU1 or the electronic unit EU2 compared to the second base structure BS2. The heat transfer coefficient (in units of W/mK) of the first heat dissipation structure HD1 of the first base structure BS1 is different from the heat transfer coefficient of the second heat dissipation structure HD2 of the second base structure BS2. In some embodiments, the heat transfer coefficient of the first heat dissipation structure HD1 is greater than the heat transfer coefficient of the second heat dissipation structure HD2, so that heat concentrated in the electronic unit may be conducted out through the connection substrate 100, thereby improving the reliability of the electronic device 10.

In some embodiments, the first insulation layer IL1 and the second insulation layer IL2 may each include multiple insulation layers alternately stacked along the Z direction. For example, as shown in FIG. 2, the first insulation layer IL1 may include an insulation layer IL1a and an insulation layer IL1b disposed on the insulation layer IL1a, and the second insulation layer IL2 may include an insulation layer IL2a and an insulation layer IL2b disposed on the insulation layer IL2a. The first insulation layer IL1 and the second insulation layer IL2 may each include organic material or inorganic material. The organic material includes polyimide (PI), poly-p-xylylene (also known as Parylene), benzocyclobutene (BCB), epoxy, polycarbonate (PC), polyethylene terephthalate (PET), polyethylene naphthalate (PEN), polymer, or other suitable organic materials, but the disclosure is not limited thereto. The inorganic material includes silicon-containing glass, silicon oxide, silicon nitride, silicon oxynitride, or other suitable inorganic materials, but the disclosure is not limited thereto. In some embodiments, the coefficient of thermal expansion of the first insulation layer IL1 and the second insulation layer IL2 may be different. For example, the coefficient of thermal expansion of one of the first insulation layer IL1 and the coefficient of thermal expansion of the electronic unit EU1 have a first difference, the first difference may be greater than or equal to 5 and less than or equal to 16, the coefficient of thermal expansion of one of the second insulation layer IL2 and the coefficient of thermal expansion of the electronic unit EU1 have a second difference, the second difference may be greater than or equal to 10 and less than or equal to 45, in which a ratio R1 of the first difference to the second difference (R1=first difference/second difference) may be greater than or equal to 0.12 and less than or equal to 5, or greater than or equal to 0.2 and less than or equal to 4, which may help improve the support of the connection substrate 100 and reduce warpage situations caused by excessive differences in coefficient of thermal expansion (CTE). The first difference and the second difference may be greater than or equal to 0.

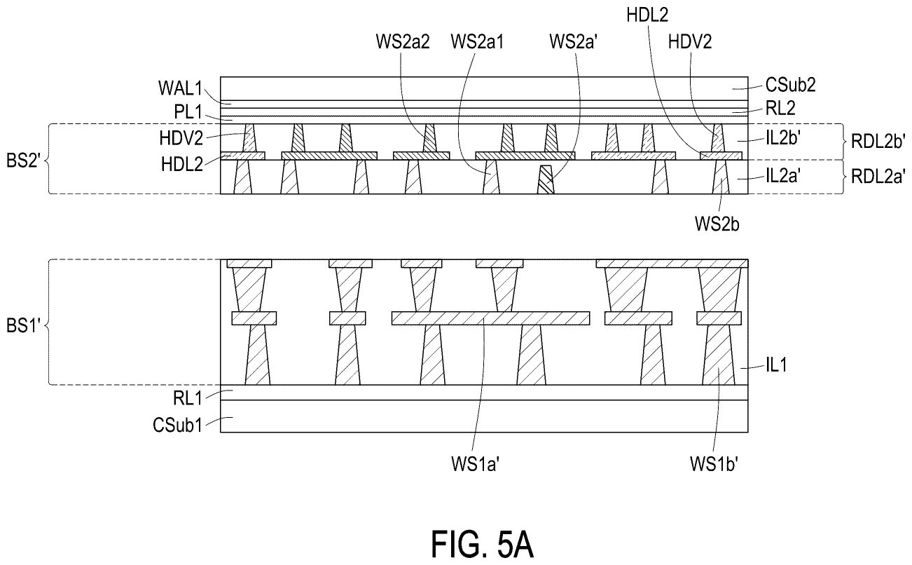

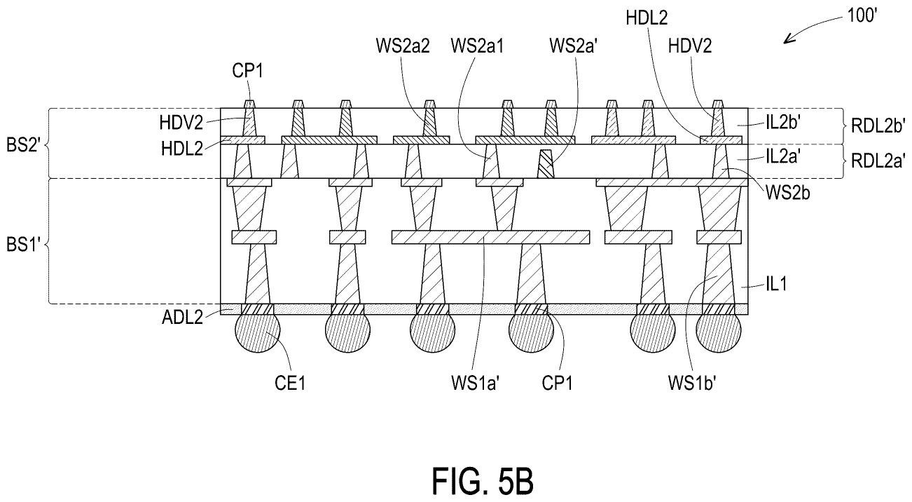

In the present embodiment, the first base structure BS1 may include a first wiring structure WS1a, and the second base structure BS2 may include a second wiring structure WS2a that electrically connects the first wiring structure WS1a to the electronic units EU1, EU2. In some embodiments, the wiring structure WS1a and the wiring structure WS2a may include multiple conductive patterns/conductive layers respectively formed in the first insulation layer IL1 and the second insulation layer IL2 and alternately stacked along the Z direction, and conductive vias connecting the conductive patterns/conductive layers. For example, as shown in FIG. 2, the wiring structure WS1a may include a wiring structure WS1a1 and a wiring structure WS1a2 disposed on the wiring structure WS1a1, and the wiring structure WS2a may include a wiring structure WS2a1 and a wiring structure WS2a2 disposed on the wiring structure WS2a1, in which the wiring structures WS1a1, WS1a2, WS2a1, WS2a2 may each include multiple conductive patterns/conductive layers and conductive vias connecting the conductive patterns/conductive layers. The first wiring structure WS1a and the second wiring structure WS2a may each include any suitable conductive material, for example copper, titanium, nickel, combinations or alloys of the aforementioned materials, but are not limited thereto. According to some embodiments, the directions of multiple conductive vias in the base structure may be the same (for example FIG. 2) or may be a mirror design (for example FIG. 5B).

Based on the above, the connection substrate 100 may serve as a core of the electronic device 10 on which the electronic units EU1, EU2 are disposed and may serve as a redistribution substrate connecting the electronic units EU1, EU2.

The thickness t1 of the first insulation layer IL1 is different from the thickness t2 of the second insulation layer IL2, in which the thickness t1 of the first insulation layer IL1 may be in a range of 6 micrometers to 15 micrometers, and the thickness t2 of the second insulation layer IL2 may be in a range of 1 micrometer to 5 micrometers. For example, the thickness t1 of the first insulation layer IL1 is designed to be greater than the thickness t2 of the second insulation layer IL2. For instance, when a ratio R2 of thickness t1 to thickness t2 (R2=thickness t1/thickness t2) is greater than or equal to 2 and less than or equal to 8, or greater than or equal to 3 and less than or equal to 6, it may help improve the support of the connection substrate 100 serving as the core of the electronic device 10, and may help reduce warpage situations caused by excessive differences in coefficient of thermal expansion (CTE). For example, the first insulation layer IL1 and the second insulation layer IL2 may cause the coefficient of thermal expansion to exhibit a gradual change through the aforementioned thickness relationship, thereby reducing warpage situations caused by excessive differences in coefficient of thermal expansion.

Designing the first heat dissipation structure HD1 and the second heat dissipation structure HD2 to overlap each other and be respectively disposed in the first insulation layer IL1 and the second insulation layer IL2 may help improve the heat dissipation efficiency of the connection substrate 100 serving as the core of the electronic device 10. In some embodiments, the first heat dissipation structure HD1 and the second heat dissipation structure HD2 may be disposed at the periphery of the connection substrate 100 to help conduct heat to the outside. In some embodiments, the first insulation layer IL1 may include a first filler, the second insulation layer IL2 may include a second filler, and a particle size of the first filler is greater than a particle size of the second filler, which may help further improve the support of the connection substrate 100. In other embodiments, the first filler and/or the second filler may include thermally conductive material with good thermal conductivity to help improve the heat dissipation efficiency of the connection substrate 100. In some embodiments, the thermally conductive material may include materials such as silicon, diamond powder, silicon carbide (SiC), metal, graphene, barium sulfide (BaS), boron nitride (BN), graphite, TiO₂, AlN, Al₂O₃, or ceramic. In some embodiments, the thermal conductivity (in units of W/mK) of the first filler and the thermal conductivity of the second filler may be the same or different. For example, the first filler may be filled with silicon carbide and the second filler may be filled with diamond powder, and the first filler and the second filler may at least be in contact with each other, thereby creating an effective heat dissipation path through this design to improve the heat dissipation effect of the electronic device.

In some embodiments, the first heat dissipation structure HD1 may include at least one heat dissipation layer HDL1 and at least one heat dissipation via HDV1 overlapping with the at least one heat dissipation layer HDL1, and the second heat dissipation structure HD2 may include at least one heat dissipation layer HDL2 and at least one heat dissipation via HDV2 overlapping with the at least one heat dissipation layer HDL2. The heat dissipation layer HDL1 and the heat dissipation via HDV1 may be integrated in the process of forming the first wiring structure WS1a, and the heat dissipation layer HDL2 and the heat dissipation via HDV2 may be integrated in the process of forming the second wiring structure WS2a. In other words, the first wiring structure WS1a or the second wiring structure WS2a may include a conductive layer disposed at the same level as the heat dissipation layer HDL1 or the heat dissipation layer HDL2 and a conductive via disposed at the same level as the heat dissipation via HDV1 or the heat dissipation via HDV2 and in contact with the conductive layer (as shown in FIG. 1).

In some embodiments, the heat dissipation layer HDL2 of the second heat dissipation structure HD2 may serve as a heat dissipation plane and be disposed in a dummy region (for example, disposed in a region where there is no path electrically connecting the electronic unit EU1 and the electronic unit EU2) of the second insulation layer IL2 below the electronic unit EU1 and the electronic unit EU2. In some embodiments, referring to FIG. 1 and FIG. 3 simultaneously, the dummy region may correspond to hot spots of the electronic unit EU1 and the electronic unit EU2, or the dummy region may overlap with the hot spots of the electronic unit EU1 and the electronic unit EU2, and a ratio R3 of a horizontal area (for example, an area observed/measured in a top view, such as a sum of an area A1 and an area A2) of the heat dissipation layer HDL2 to a horizontal area of the electronic unit EU1 and the electronic unit EU2 may be in a range greater than or equal to 20% and less than or equal to 40%. It is worth noting that in a situation where the heat dissipation layer HDL2 is rectangular, the area A1 and the area A2 may be obtained by multiplying a dimension of the heat dissipation layer HDL2 in an X direction by a dimension in a Y direction, but the disclosure is not limited thereto.

In some embodiments, as shown in FIG. 3, the heat dissipation layer HDL2 and the conductive layer of the wiring structure WS2a may be disposed at the same level and spaced apart from each other, and the heat dissipation via HDV2 and the conductive via of the wiring structure WS2a may be disposed at the same level and spaced apart from each other. In other embodiments, the heat dissipation layer HDL2 and the conductive layer of the wiring structure WS2a may be disposed at different levels, for example, the heat dissipation layer HDL2 and the conductive layer of the wiring structure WS2a may be respectively disposed in the insulation layer IL2a and the insulation layer IL2b shown in FIG. 2. In embodiments where the heat dissipation layer HDL2 and the wiring structure WS2a overlap in the Z direction, the conductive via of the wiring structure WS2a may pass through the heat dissipation layer HDL2 to transmit electrical signals to conductive layers at other levels, and the heat dissipation via HDV2 may also pass through the conductive layer of the wiring structure WS2a to transmit heat to heat dissipation layers at other levels. In a situation where the heat dissipation layer HDL2 includes conductive material, the conductive via of the wiring structure WS2a may pass through the heat dissipation layer HDL2 without contacting the heat dissipation layer HDL2 (for example, the heat dissipation layer HDL2 may include an opening for the conductive via to pass through, but the disclosure is not limited thereto). In a situation where the heat dissipation via HDV2 includes conductive material, the heat dissipation via HDV2 may pass through the conductive layer of the wiring structure WS2a without contacting the wiring structure WS2a (for example, the conductive layer of the wiring structure WS2a may include an opening for the heat dissipation via HDV2 to pass through, but the disclosure is not limited thereto).

In the present embodiment, the second base structure BS2 may include a wiring structure WS2b connecting the first heat dissipation structure HD1 and the second heat dissipation structure HD2, such that heat from the electronic units EU1, EU2 may not only be transmitted to the adjacent second heat dissipation structure HD2, but may also be further transmitted to the first heat dissipation structure HD1 below through the wiring structure WS2b, thereby improving the heat dissipation efficiency of the electronic device 10. In the present embodiment, the first base structure BS1 may include a wiring structure WS1b connecting the first heat dissipation structure HD1, such that heat may also be further transmitted through the wiring structure WS1b to heat dissipation structures (for example, heat dissipation structures in an external component 200) in components below, thereby improving the heat dissipation efficiency of the electronic device 10.

In some embodiments, as shown in FIG. 1 and FIG. 4, the first base structure BS1 or the second base structure BS2 may include a support layer SL disposed in the first insulation layer IL1 or the second insulation layer IL2, which may help adjust the support and coefficient of thermal expansion of the connection substrate 100. As shown in FIG. 4, the support layer SL may be disposed in the second insulation layer IL2 of the second base structure BS2, but the disclosure is not limited thereto, and the support layer SL may also be disposed in the first insulation layer IL1 of the first base structure BS1. In some embodiments, the support layer SL and the conductive layer of the wiring structure WS2a may be disposed at different levels, for example, the support layer SL and the conductive layer of the wiring structure WS2a may be respectively disposed in the insulation layer IL2a and the insulation layer IL2b shown in FIG. 2. In some embodiments, as shown in FIG. 4, the support layer SL may be disposed above some wiring layers WS2ao in the wiring structure WS2a. In some embodiments, when the support layer SL includes conductive material, the support layer SL may be disposed above the wiring layer WS2ao without contacting the wiring layer WS2ao. In other embodiments, when the support layer SL includes insulation material, the support layer SL may be disposed on the wiring layer WS2ao and contact the wiring layer WS2ao.

In other embodiments, the support layer SL may include heat dissipation material and serve as a heat dissipation layer to contact with a stiffener SR1 to be mentioned subsequently, which may help improve heat dissipation efficiency. For example, the support layer SL may include metal material (such as copper, titanium, molybdenum, or aluminum), alloy material (such as invar, also referred to as nickel steel alloy), ceramic material (such as boron nitride or silicon carbide), carbon material having specific thermal conduction direction or good thermal conduction capability (such as graphene or carbon nanotube), or combinations thereof. In some embodiments, when the support layer SL is alloy material, the thickness of the support layer SL may be in a range of 10 micrometers to 30 micrometers. In embodiments where the support layer SL serves as a heat dissipation layer, the heat dissipation via HDV2 may be thermally coupled to the support layer SL, such that thermal energy generated by the electronic unit EU1 or the electronic unit EU2 may be transmitted to other places through the heat dissipation via HDV2 and the support layer SL, which may help improve heat dissipation efficiency. In some embodiments, a thermal interface layer TIM1 may be provided between the support layer SL and the stiffener SR1 to help the efficiency of heat transmission, but the disclosure is not limited thereto.

In other embodiments, the support layer SL may be disposed below the wiring layer WS2ao or disposed at the same level as the wiring structure WS2a. In embodiments where the support layer SL and the wiring layer WS2ao overlap in the Z direction (for example, the support layer SL may be disposed above or below the wiring layer WS2ao), the conductive via of the wiring structure WS2a may pass through the support layer SL to transmit electrical signals to conductive layers at other levels, and the heat dissipation via HDV2 may also pass through the wiring layer WS2ao to transmit heat to heat dissipation layers at other levels. When the support layer SL includes conductive material, the conductive via of the wiring structure WS2a may pass through the support layer SL without contacting the support layer SL (for example, the support layer SL may include an opening for the conductive via to pass through, but the disclosure is not limited thereto). When the support layer SL includes conductive material and is disposed at the same level as the wiring structure WS2a, the support layer SL and the wiring structure WS2a may be spaced apart from each other.

In some embodiments, the support layer SL disposed in the second insulation layer IL2 and the support layer SL disposed in the first insulation layer IL1 may have different dimensions, which may respond to heat dissipation efficiency and support performance of different requirements. For example, the support layer SL disposed in the second insulation layer IL2 may have dimensions larger than the support layer SL disposed in the first insulation layer IL1 because it is adjacent to the electronic units EU1, EU2, which may help improve heat dissipation efficiency (when the support layer SL includes heat dissipation material), or enable the coefficient of thermal expansion (CTE) of the connection substrate 100 to present gradual changes according to requirements, which may help improve the reliability of the electronic device 10. In some embodiments, the support layer SL may be configured near the center of the connection substrate 100 (for example, at the center in the horizontal direction) to adjust the coefficient of thermal expansion of the connection substrate 100 or improve the stability of the connection substrate 100.

The first base structure BS1 may include the first heat dissipation structure HD1 and/or the support layer SL, and the second base structure BS2 may include the second heat dissipation structure HD2 and/or the support layer SL. In embodiments where the first base structure BS1 includes the first heat dissipation structure HD1 and the support layer SL, the first heat dissipation structure HD1 and the support layer SL may be respectively disposed in different insulation layers in the first insulation layer IL1, for example in the insulation layer IL1a and the insulation layer IL1b, but the disclosure is not limited thereto. In embodiments where the second base structure BS2 includes the second heat dissipation structure HD2 and the support layer SL, the second heat dissipation structure HD2 and the support layer SL may be respectively disposed in different insulation layers in the second insulation layer IL2, for example in the insulation layer IL2a and the insulation layer IL2b, but the disclosure is not limited thereto.

Referring to FIG. 1 still, in this embodiment, the coefficient of thermal expansion of the connection substrate 100 may be calculated through the following method. The volume occupied by the first insulation layer IL1 of the first base structure BS1 is V_{A1}, and has a coefficient of thermal expansion with a value of CTE_{A1}, while the volume occupied by the wiring structures WS1a, WS1b of the first base structure BS1 is V_{B1}, and has a coefficient of thermal expansion with a value of CTE_{B1}. The volume occupied by the second insulation layer IL2 of the second base structure BS2 is V_{A2}, and has a coefficient of thermal expansion with a value of CTE_{A2}, while the volume occupied by the wiring structures WS2a, WS2b of the second base structure BS2 is V_{B2}, and has a coefficient of thermal expansion with a value of CTE_{B2}. The coefficient of thermal expansion of the connection substrate 100 may be the sum of V_{A1}*(CTE_{A1})/(V_{A1}+V_{B1}+VA₂+V_{B2}), V_{B1}*(CTE_{B1})/(V_{A1}+V_{B1}+V_{A2}+V_{B2}), V_{A2}*(CTE_{A2})/(V_{A1}+V_{B1}+V_{A2}+V_{B2}), and V_{B2}*(CTE_{B2})/(V_{A1}+V_{B1}+V_{A2}+V_{B2}).

In this embodiment, the connection substrate 100 may include a first adjustment layer ADL1 disposed between the first base structure BS1 and the second base structure BS2, so as to help adjust the coefficient of thermal expansion of the connection substrate 100 (for example, the aforementioned calculation method of the coefficient of thermal expansion includes the coefficient of thermal expansion of the first adjustment layer ADL1 and the volume occupied thereby). In some embodiments, a coefficient of thermal expansion of the first adjustment layer ADL1 is less than a coefficient of thermal expansion of the first insulation layer IL1 and the second insulation layer IL2. In some embodiments, the first adjustment layer ADL1 may exemplify organic materials, polymers, epoxy resin, oxides, silicon dioxide, silicon nitride, but the disclosure is not limited thereto. In some embodiments, the thermal conductivity coefficient of the first adjustment layer ADL1 may be between the thermal conductivity coefficient of the first base structure BS1 and the thermal conductivity coefficient of the second base structure BS2.

In some embodiments, the connection substrate 100 may include a second adjustment layer ADL2, where the second adjustment layer ADL2 is disposed at a side of the first base structure BS1 away from the second base structure BS2. The second adjustment layer ADL2 may exemplify polymers, epoxy resin, but the disclosure is not limited thereto. In some embodiments, the second adjustment layer ADL2 may exemplify an anti-warpage layer to help improve the warpage situation of the connection substrate 100. The anti-warpage layer may be a single-layer or multi-layer structure including organic materials and/or inorganic materials, similar with the first insulation layer.

In some embodiments, the connection substrate 100 may include a pad CP1, a pad CP2, and a pad CP3. The pad CP1 may be disposed in the second adjustment layer ADL2, so as to connect the wiring structure WS1a and the wiring structure WS1b in the first base structure BS1 to the external assembly 200 below. The pad CP2 may be disposed in the first adjustment layer ADL1 to connect the wiring structure WS1a and the wiring structure WS1b in the first base structure BS1 to the wiring structure WS2a and the wiring structure WS2b of the second base structure BS2 above. The pad CP3 may be disposed between the second base structure BS2 and the electronic units EU1, EU2, so as to connect the electronic units EU1, EU2 to the second base structure BS2 below. In some embodiments, the pad CP1, the pad CP2, and the pad CP3 may each include signal pads through which signal paths (for example, paths passing through the wiring structure WS1a and the wiring structure WS2a) pass and heat dissipation pads through which heat dissipation paths (for example, paths passing through the wiring structure WS1b and the wiring structure WS2b) pass. The pad CP1, the pad CP2, and the pad CP3 may each include materials having good conductive and heat conductive characteristics. For example, the pad CP1, the pad CP2, and the pad CP3 may include materials such as copper (Cu), aluminum (Al), nickel (Ni), or molybdenum (Mo).

In the present embodiment, the electronic device 10 further includes an external assembly 200, a heat dissipation component 300, and a stiffener SR1. In some embodiments, the external assembly 200 may be a circuit substrate (for example, a printed circuit board), but the disclosure is not limited thereto. In the present embodiment, the external assembly 200 may be disposed below the connection substrate 100 and connect the connection substrate 100 to the external assembly 200 through a conductive element CE1 disposed between the connection substrate 100 and the external assembly 200. In some embodiments, the conductive element CE1 may include solder balls. The material of the conductive element CE1 may include tin-silver (SnAg), tin, silver, nickel, gold, copper, conductive adhesive, or other suitable conductive materials, but the disclosure is not limited thereto. In the present embodiment, the conductive element CE1 may ensure the connection path between the connection substrate 100 and the external assembly 200 through underfill UF1 disposed between the external assembly 200 and the connection substrate 100 and surrounding the conductive element CE1, thereby improving the reliability of the electronic device 10. In the present embodiment, the first wiring structure WS1a and the second wiring structure WS2a may electrically connect the electronic units EU1, EU2 to the external assembly 200.

In the present embodiment, the heat dissipation component 300 may be disposed above the electronic units EU1, EU2 and may include a heat dissipation substrate 302 and a heat dissipation structure 304 disposed on the heat dissipation substrate 302. The heat dissipation substrate 302 and the heat dissipation structure 304 may each include any suitable heat conductive material. In the present embodiment, the heat dissipation structure 304 may be, for example, heat dissipation fins having a fin-like structure. In some embodiments, a thermal interface layer TIM1 may be provided between the electronic units EU1, EU2 and the heat dissipation component 300 to help the efficiency of heat transmission, but the disclosure is not limited thereto. In some embodiments, a thermal interface layer TIM1 may be provided between the stiffener SR1 and the heat dissipation component 300 to help the efficiency of heat transmission, but the disclosure is not limited thereto. In some embodiments, a thermal interface layer TIM1 may be provided between the stiffener SR1 and the external assembly 200 to help the efficiency of heat transmission, but the disclosure is not limited thereto.

In the present embodiment, the stiffener SR1 may be disposed around the connection substrate 100 and between the heat dissipation component 300 and the external assembly 200, in which the heat dissipation layers HDL1, HDL2 may extend laterally and contact the stiffener SR1, such that heat may be transmitted from the heat dissipation layers to the stiffener SR1 and then transmitted to the heat dissipation component 300 above. In some embodiments, the heat dissipation layers HDL1, HDL2 may extend laterally and directly contact the stiffener SR1. In other embodiments, a thermal interface layer TIM1 may be provided between the support layer SL and the stiffener SR1 to help the efficiency of heat transmission, but the disclosure is not limited thereto. In other embodiments, the stiffener SR1 may include thermal interface material thermally coupled with the support layer SL to provide an interface for thermal coupling between the two components. In some embodiments, the stiffener SR1 may be a stiffener ring surrounding the connection substrate 100. The stiffener SR1 may include any suitable heat conductive material, for example, metal, conductive adhesive material, or combinations thereof, for example, copper, aluminum, thermal interface material, or combinations thereof, to enhance the heat dissipation efficiency of the electronic device 10. In the present embodiment, along a direction (such as the X direction) perpendicular to the Z direction, the heat dissipation layers HDL1, HDL2 and the heat dissipation vias HDV1, HDV2 may be closer to the stiffener SR1 compared to the conductive layers and conductive vias (for example, the conductive layers and conductive vias included in the first wiring structure WS1a or the second wiring structure WS2a), that is, in the X direction, the heat dissipation layer HDL1 is disposed between the first wiring structure WS1a and the stiffener SR1 to facilitate conducting heat out of the electronic device 10.

Hereinafter, a method for manufacturing an electronic device will be described with reference to FIG. 1 and FIG. 2, but the manufacturing method of the electronic device 10 is not limited thereto and the same or similar components are represented by the same or similar element symbols, so details will not be repeated here. FIG. 2 is a cross-sectional schematic diagram of the connection substrate in FIG. 1 according to an embodiment of the disclosure.

Referring to FIG. 1, the method of manufacturing the electronic device 10 may include the following steps. First, at least one electronic unit EU1 or EU2 is provided. Next, a connection substrate 100 is provided, in which the connection substrate 100 is electrically connected to the electronic unit EU1 or EU2 and includes a first base structure BS1 and a second base structure BS2 disposed between the first base structure BS1 and the electronic unit EU1 or EU2. In the present embodiment, the first base structure BS1 includes a first insulation layer IL1 and a first heat dissipation structure HD1 formed in the first insulation layer IL1, and the second base structure BS2 includes a second insulation layer IL2 and a second heat dissipation structure HD2 formed in the second insulation layer IL2. The thickness t1 of the first insulation layer IL1 is greater than the thickness t2 of the second insulation layer IL2, and the first heat dissipation structure HD1 overlaps with the second heat dissipation structure HD2. In some embodiments, the method of manufacturing the electronic device 10 may further include the following steps. A heat dissipation component 300 is provided above the electronic units EU1, EU2. An external assembly 200 is provided below the connection substrate 100, in which the external assembly 200 is electrically connected to the connection substrate 100. Also, a stiffener SR1 is provided around the connection substrate 100, in which the stiffener SR1 may be formed between the heat dissipation component 300 and the external assembly 200, and the heat dissipation layers HDL1, HDL2 are in contact with the stiffener SR1.

In some embodiments, the first insulation layer IL1 or the second insulation layer IL2 may include a first part formed using a first photolithography process using a half-tone mask or a gray-tone mask. In some embodiments, the first insulation layer IL1 or the second insulation layer IL2 may include a second part formed using a second photolithography process different from the first photolithography process. The second photolithography process uses a photomask different from the half-tone mask or the gray-tone mask, in which a light transmittance through the photomask is greater than the light transmittance through the half-tone mask or the gray-tone mask.

For example, as shown in FIG. 2, the first base structure BS1 may include a redistribution layer RDL1a and a redistribution layer RDL1b located on the redistribution layer RDL1a. The insulation layer IL1a may use a photomask different from the half-tone mask or the gray-tone mask to form via holes and grooves in the insulation layer IL1a in which the wiring structure WS1a1 and the wiring structure WS1b are formed. The insulation layer IL1b may use a half-tone mask or a gray-tone mask to form via holes of different depths in the insulation layer IL1b. For example, the depth of the via hole in which the wiring structure WS1a2 is formed may be greater than the depth of the via hole in which the heat dissipation via HDV1 is formed. That is, the process of forming the redistribution layer RDL1a may be different from the process of forming the redistribution layer RDL1b.

Similarly, as shown in FIG. 2, the second base structure BS2 may include a redistribution layer RDL2a and a redistribution layer RDL2b located on the redistribution layer RDL2a. The insulation layer IL2a may use a photomask different from the half-tone mask or the gray-tone mask to form via holes and grooves in the insulation layer IL2a in which the wiring structures WS2a1, WS2b are formed. The insulation layer IL2b may use a half-tone mask or a gray-tone mask to form via holes of different depths in the insulation layer IL2b. For example, the depth of the via hole in which the wiring structure WS2a2 is formed may be greater than the depth of the via hole in which the heat dissipation via HDV2 is formed. That is, the process of forming the redistribution layer RDL2a may be different from the process of forming the redistribution layer RDL2b.

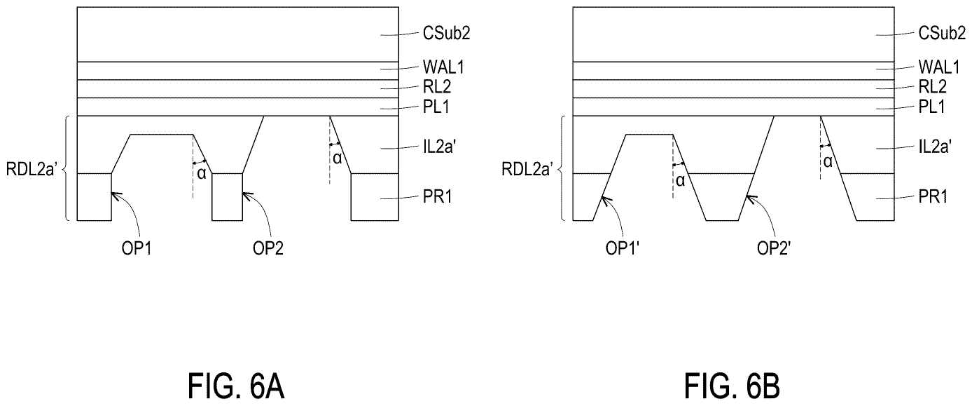

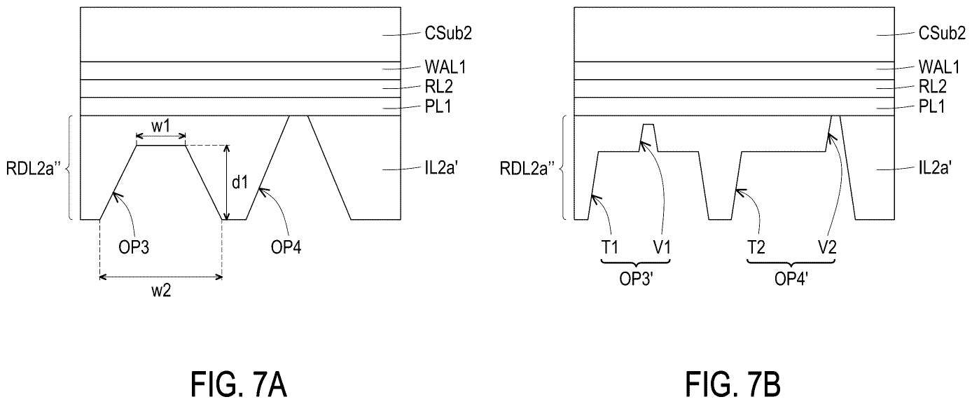

FIG. 5A and FIG. 5B are cross-sectional schematic diagrams of a method for manufacturing a connection substrate according to an embodiment of the disclosure. FIGS. 6A and 6B and FIG. 7A and FIG. 7B are cross-sectional schematic diagrams of partial steps of a method for forming the redistribution layer in FIG. 5B according to different embodiments of the disclosure.

Hereinafter, a method for manufacturing a connection substrate 100′ in another embodiment will be exemplified through FIG. 5A and FIG. 5B.

Referring to FIG. 5A, first, a carrier substrate CSub1 is provided. In some embodiments, the material of the carrier substrate CSub1 may include glass, quartz, sapphire, ceramic, stainless steel, silicon wafer, other suitable substrate materials, or combinations thereof, but the disclosure is not limited thereto. Next, a release layer RL1 is provided on the carrier substrate CSub1. In some embodiments, the release layer RL1 may be a temporary bonding layer, which may include adhesive thermal-type release material or optical-type release material, so that subsequently formed working units, components, or film layers may be temporarily bonded to the release layer RL1. In other words, the release layer RL1 may assist in removing working units, components, or film layers subsequently formed on the carrier substrate CSub1 from the carrier substrate CSub1. When thermal-type release material is used to form the release layer RL1, the thermal-type release material loses adhesiveness when heated, so that components or film layers formed thereon may be peeled from the release layer RL1. For example, the release layer RL1 may be thermal release tape (TRT) or light-to-heat-conversion (LTHC) release coating. When optical-type release material is used to form the release layer RL1, the optical release material loses adhesiveness when exposed to radiation such as ultra-violet light (UV light), so that components or film layers formed thereon may be peeled from the release layer RL1. Next, a first base structure BS1′ is formed on the release layer RL1. In this embodiment, the first base structure BS1′ may include an insulation layer IL1 and wiring structures WS1a′, WS1b′ formed in the insulation layer IL1.

Then, a carrier substrate CSub2 is provided. In some embodiments, the carrier substrate CSub2 may adopt the materials listed for the carrier substrate CSub1, but the disclosure is not limited thereto. Next, an anti-warpage layer WAL1, a release layer RL2, and a protection layer PL1 are sequentially provided on the carrier substrate CSub2. The release layer RL2 may adopt the materials listed for the release layer RL1, but the disclosure is not limited thereto. The protection layer PL1 may include any suitable material. Next, a second base structure BS2′ is formed on the protection layer PL1.

In the present embodiment, the second base structure BS2′ may include a redistribution layer RDL2a′ and a redistribution layer RDL2b′ located on the redistribution layer RDL2a′. The insulation layer IL2a′ may use a half-tone mask or a gray-tone mask to form via holes of different depths in the insulation layer IL2a′. For example, the depth of the via holes in which the wiring structures WS2a1, WS2b are formed may be greater than the depth of the via holes in which a functional component WS2a′ is formed. The insulation layer IL2b′ may use a half-tone mask or a gray-tone mask to form via holes of different depths in the insulation layer IL2b′. For example, the depth of the via holes in which the wiring structure WS2a2 is formed may be greater than the depth of the via holes in which the heat dissipation via HDV2 is formed.

Then, referring to FIG. 5A and FIG. 5B, the second base structure BS2′ may be bonded to the first base structure BS1′ through hybrid bonding. In the present embodiment, the interface where the first base structure BS1′ and the second base structure BS2′ are bonded to each other includes metal-to-metal bonding between the wiring structures WS2a1, WS2b and the wiring structure WS1a′, and oxide-to-oxide bonding or PI-PI (polyimide to polyimide) bonding between the insulation layer IL2a′ and the insulation layer IL1.

In some embodiments, the functional component WS2a′ may be a protection circuit formed in the insulation layer IL2a′ and connected to a ground level. In the present embodiment, the functional component WS2a′ may be a protection circuit connected to the ground level formed by filling metal (such as copper) in a groove. In other embodiments, the functional component WS2a′ may also be a protection circuit connected to the ground level formed by filling conductive adhesive material in a groove. In some embodiments, filler may be added to the conductive adhesive material to adjust the coefficient of thermal expansion and/or increase heat dissipation efficiency. The filler dimension may be in a range of 0.1 micrometers to 100 micrometers. The filler may include thermally conductive materials such as graphene, graphite, TiO₂, AlN, Al₂O₃, or ceramic, or materials with low coefficient of thermal expansion such as silicon dioxide. In some alternative embodiments, the functional component WS2a′ may also be formed by filling any adhesive material containing filler capable of adjusting the coefficient of thermal expansion and/or increasing heat dissipation efficiency in a groove, so as to form a functional component that adjusts the coefficient of thermal expansion and/or increases heat dissipation efficiency. In some other embodiments, the functional component WS2a′ may also be formed by filling material (such as Invar 36) capable of enhancing support strength and/or increasing heat dissipation efficiency in a groove, so as to form a functional component that enhances support strength and/or increases heat dissipation efficiency. In embodiments where the functional component serves a heat dissipation function, it may be connected to a heat dissipation path through other heat dissipation layers in another cross-section.

Referring to FIG. 5B and FIG. 6A, an opening OP1 in the redistribution layer RDL2a′ may be the opening OP1 in which the functional component WS2a′ is formed, and the opening OP2 in the redistribution layer RDL2a′ may be the opening OP2 in which the wiring structure WS2a1 is formed. In some embodiments, the opening OP1 and the opening OP2 may be formed by using a mask PR1 (such as a half-tone mask or a gray-tone mask) formed on the insulation layer IL2a′ as an etching mask and through corresponding photolithography processes. In some embodiments, the opening OP1 and the opening OP2 have different shapes and dimensions, so the metal (such as copper) filled therein may also have different volumes, which may help adjust the coefficient of thermal expansion of the redistribution layer RDL2a′. That is, the functional component WS2a′ may be formed in desired regions in the redistribution layer RDL2a′ according to requirements, to help adjust the warpage situation of the redistribution layer RDL2a′. In some embodiments, the opening OP1 and the opening OP2 may include sidewalls having an angle α with the normal direction of the bottom surfaces thereof. The angle α may be in a range of 30° to 85°. In other embodiments, openings with different shapes (such as the opening OP1′ and the opening OP2′ shown in FIG. 6B) may be formed in the insulation layer IL2a′ through different masks.

In some embodiments, as shown in FIG. 7A and FIG. 7B, different methods (such as excimer laser) may be used to form an opening OP3 and an opening OP4 in the insulation layer IL2a′, where the opening OP3 in a redistribution layer RDL2a″ may be the opening OP3 in which the functional component WS2a′ is formed, and the opening OP4 in the redistribution layer RDL2a″ may be the opening OP4 in which the wiring structure WS2a1 is formed. In this embodiment, the opening OP3 in which the functional component WS2a′ is formed may have a depth d1 and a bottom dimension w1 and a top dimension w2, where the ratio of the bottom dimension w1 to the depth d1 may be in a range of 0.3 to 1, and the bottom dimension w1 may be greater than or equal to 1 micrometer. In this embodiment, the top dimension w2 of the opening OP3 may be greater than the bottom dimension w1 of the opening OP3.

In other embodiments, as shown in FIG. 7B, an opening OP3′ may include a via hole V1 and a trench T1 connected to the via hole V1, and an opening OP4′ may include a via hole V2 and a trench T2 connected to the via hole V2. That is, the opening OP3′ in which the functional component WS2a′ is formed and the opening OP4′ in which the wiring structure WS2a1 is formed may also be formed in combination with a dual-damascene process.

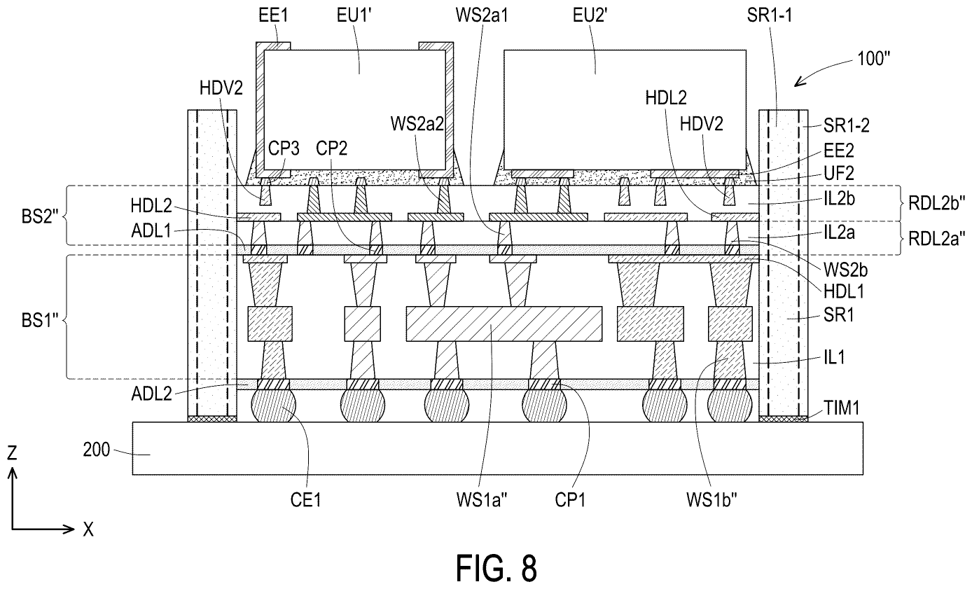

FIG. 8 is a cross-sectional schematic diagram of a connection substrate according to another embodiment of the disclosure. A connection substrate 100″ shown in FIG. 8 is similar to the connection substrate 100′shown in FIG. 5B, with the difference being that a first base structure BS1″ and a second base structure BS2″ of the connection substrate 100″ are different from the first base structure BS1′ and the second base structure BS2′ of the connection substrate 100′, while other same or similar components are represented by same or similar reference numerals, so details will not be repeated here.

Referring to FIG. 8, the first base structure BS1″ may include an insulation layer IL1 and wiring structures WS1a″, WS1b″ formed in the insulation layer IL1, and the second base structure BS2″ may include a redistribution layer RDL2a″ and a redistribution layer RDL2b″ located on the redistribution layer RDL2a″. The insulation layer IL2a may use a photomask different from a half-tone mask or a gray-tone mask to form via holes and trenches in the insulation layer IL2a in which the wiring structures WS2a1, WS2b are formed. The insulation layer IL2b may use a half-tone mask or a gray-tone mask to form via holes of different depths in the insulation layer IL2b. For example, the depth of the via hole in which the wiring structure WS2a2 is formed may be greater than the depth of the via hole in which the heat dissipation via HDV2 is formed. That is, the process for forming the redistribution layer RDL2a″ may be different from the process for forming the redistribution layer RDL2b″.

In the present embodiment, the process for the wiring structures WS1a″, WS1b″ formed in the insulation layer IL1 may include a laser drilling process, while the process for the wiring structures WS2a1, WS2b formed in the insulation layer IL2a and/or the wiring structure WS2a2 and the heat dissipation via HDV2 and heat dissipation layer HDL2 in the heat dissipation structure formed in the insulation layer IL2b may include a photolithography process. That is, a dimension of the conductive layer or conductive via of the wiring structures WS1a″, WS1b″ formed in the insulation layer IL1 may be greater than a dimension of the conductive layer or conductive via of the wiring structures WS2a1, WS2b formed in the insulation layer IL2a, or may be greater than a dimension of the conductive layer or conductive via of the wiring structure WS2a2 formed in the insulation layer IL2b and dimensions of the heat dissipation via HDV2 and heat dissipation layer HDL2 in the heat dissipation structure. The dimension referred to in the disclosure may include any one of thickness, height, or width.

In the present embodiment, an electronic unit EU1′ and an electronic unit EU2′ may be disposed on the connection substrate 100″, in which the electronic unit EU1′ may be electrically connected to the connection substrate 100″ through a terminal electrode EE1, and the electronic unit EU2′ may be electrically connected to the connection substrate 100″ through a terminal electrode EE2. The terminal electrode EE1 may extend from the bottom side of the electronic unit EU1′ and contact the pad CP3 and extend along the sidewall of the electronic unit EU1′ to the top side of the electronic unit EU1′. The terminal electrode EE2 may be disposed on the bottom side of the electronic unit EU2′ and contact the pad CP3. The terminal electrode EE1 and the terminal electrode EE2 may each include any suitable conductive material.

In the present embodiment, the stiffener SR1 may be a composite structure. The stiffener SR1 may include a stack of any suitable thermally conductive material, such as metal, conductive adhesive material, or combinations thereof, such as copper, aluminum, thermal interface material, or combinations thereof, to enhance the heat dissipation efficiency of the electronic device 10. The stiffener SR1 may have a first sub-part SR1-1 and a second sub-part SR1-2, in which, in the X direction, the second sub-part SR1-2 is disposed between the first sub-part SR1-1 and the first base structure BS1″ and the second base structure BS2″, and the toughness of the second sub-part SR1-2 may be between the first sub-part SR1-1 and the insulation layer IL1 of the first base structure BS1″ and the insulation layer IL2 of the second base structure BS2″. The toughness referred to in the disclosure may be measured through a universal testing machine to measure the stress-strain curve of a sample, and the area enclosed under the stress-strain curve is called the toughness of the material.

In summary, in the embodiments of the disclosure, the first heat dissipation structure of the connection substrate is designed to overlap with the second heat dissipation structure, and the first heat dissipation structure and the second heat dissipation structure are in contact with at least a portion of the stiffener, which may help improve the heat dissipation efficiency and support of the connection substrate, thereby improving the reliability of the electronic device.

What is claimed is:

1. An electronic device, comprising:
at least one electronic unit;
a connection substrate electrically connected to the electronic unit, and comprising a first base structure and a second base structure disposed between the first base structure and the electronic unit; and
a stiffener surrounding the connection substrate,
wherein the first base structure comprises a first insulation layer and a first heat dissipation structure disposed in the first insulation layer, the second base structure comprises a second insulation layer and a second heat dissipation structure disposed in the second insulation layer, the first heat dissipation structure overlaps with the second heat dissipation structure, and the first heat dissipation structure and the second heat dissipation structure are in contact with at least a portion of the stiffener.

2. The electronic device according to claim 1, wherein the first insulation layer comprises a first filler, the second insulation layer comprises a second filler, a thickness of the first insulation layer is greater than a thickness of the second insulation layer, and a particle size of the first filler is greater than a particle size of the second filler.

3. The electronic device according to claim 1, wherein the connection substrate comprises a first adjustment layer disposed between the first base structure and the second base structure.

4. The electronic device according to claim 3, wherein a coefficient of thermal expansion of the first adjustment layer is less than a coefficient of thermal expansion of the first insulation layer and the second insulation layer.

5. The electronic device according to claim 1, wherein the first heat dissipation structure comprises at least one first heat dissipation layer and at least one first heat dissipation via overlapping with the at least one first heat dissipation layer, and the second heat dissipation structure comprises at least one second heat dissipation layer and at least one second heat dissipation via overlapping with the at least one second heat dissipation layer.

6. The electronic device according to claim 5, wherein the first base structure or the second base structure comprises a support layer disposed in the first insulation layer or the second insulation layer.

7. The electronic device according to claim 5, further comprising:
a heat dissipation component disposed above the electronic unit; and
an external assembly disposed below the connection substrate, and electrically connected to the connection substrate.

8. The electronic device according to claim 7, wherein the first base structure comprises a first wiring structure, the second base structure comprises a second wiring structure, and the first wiring structure and the second wiring structure electrically connect the electronic unit to the external assembly,
wherein the first wiring structure or the second wiring structure comprises a conductive layer disposed at same level as the at least one first heat dissipation layer or the at least one second heat dissipation layer, and a conductive via disposed at same level as the at least one first heat dissipation via or the at least one second heat dissipation via, and the conductive layer is in contact with the conductive via.

9. The electronic device according to claim 8, wherein the at least one first heat dissipation layer or the at least one second heat dissipation layer is closer to the stiffener compared to the conductive layer, and the at least one first heat dissipation via or the at least one second heat dissipation via is closer to the stiffener compared to the conductive via.

10. The electronic device according to claim 8, wherein a thickness of the conductive layer of the first wiring structure is greater than a thickness of the conductive layer of the second wiring structure.

11. A method for manufacturing an electronic device, comprising:
providing at least one electronic unit;
providing a connection substrate, wherein the connection substrate is electrically connected to the electronic unit, and comprises a first base structure and a second base structure disposed between the first base structure and the electronic unit; and
providing a stiffener surrounding the connection substrate,
wherein the first base structure comprises a first insulation layer and a first heat dissipation structure formed in the first insulation layer, and the second base structure comprises a second insulation layer and a second heat dissipation structure formed in the second insulation layer, the first heat dissipation structure overlaps with the second heat dissipation structure, and the first heat dissipation structure and the second heat dissipation structure are in contact with at least a portion of the stiffener.

12. The method according to claim 11, wherein the first insulation layer comprises a first filler, the second insulation layer comprises a second filler, a thickness of the first insulation layer is greater than a thickness of the second insulation layer, and a particle size of the first filler is greater than a particle size of the second filler.

13. The method according to claim 11, wherein the first insulation layer or the second insulation layer comprises a first part formed using a first photolithography process using a half-tone mask or a gray-tone mask.

14. The method according to claim 13, wherein the first insulation layer or the second insulation layer comprises a second part formed using a second photolithography process different from the first photolithography process, the second photolithography process uses a photomask different from the half-tone mask or the gray-tone mask, and a light transmittance through the photomask is greater than a light transmittance through the half-tone mask or the gray-tone mask.

15. The method according to claim 11, wherein the connection substrate comprises a first adjustment layer provided between the first base structure and the second base structure, and a coefficient of thermal expansion of the first adjustment layer is less than a coefficient of thermal expansion of the first insulation layer and the second insulation layer.

16. The method according to claim 11, wherein the first heat dissipation structure comprises at least one first heat dissipation layer and at least one first heat dissipation via overlapping with the at least one first heat dissipation layer, and the second heat dissipation structure comprises at least one second heat dissipation layer and at least one second heat dissipation via overlapping with the at least one second heat dissipation layer.

17. The method according to claim 16, further comprising:
providing a heat dissipation component above the electronic unit; and
providing an external assembly below the connection substrate, wherein the external assembly is electrically connected to the connection substrate.

18. The method according to claim 17, wherein the first base structure comprises a first wiring structure, the second base structure comprises a second wiring structure, and the first wiring structure and the second wiring structure electrically connect the electronic unit to the external assembly,
wherein the first wiring structure or the second wiring structure comprises a conductive layer disposed at same level as the at least one first heat dissipation layer or the at least one second heat dissipation layer, and a conductive via disposed at same level as the at least one first heat dissipation via or the at least one second heat dissipation via, and the conductive layer is in contact with the conductive via.

19. The method according to claim 18, wherein the at least one first heat dissipation layer or the at least one second heat dissipation layer is closer to the stiffener compared to the conductive layer, and the at least one first heat dissipation via or the at least one second heat dissipation via is closer to the stiffener compared to the conductive via.

20. The method according to claim 18, wherein a thickness of the conductive layer of the first wiring structure is greater than a thickness of the conductive layer of the second wiring structure.
